(19) United States
(12) Patent Application Publication
(10) Pub. No.: US 2011/0045658 A1
(43) Pub. Date: Feb. 24, 2011

(54) METHOD FOR FABRICATING A SEMI-POLAR NITRIDE SEMICONDUCTOR

(76) Inventors: Hsueh-hsing LIU, Jung-li City (TW); Jen-inn Chyi, Jung-li City (TW); Chin-chi Wu, Jung-li City (TW)

Correspondence Address: Muncy, Geissler, Olds & Lowe, PLLC, 4000 Legato Road, Suite 310, FAIRFAX, VA, 22033, US

(21) Appl. No.: 12/641,030

(22) Filed: Dec. 17, 2009

(30) Foreign Application Priority Data
Aug. 21, 2009 (TW) 98128191

(51) Int. Cl. H01L 21/20

(52) U.S. Cl. 438/478; 257/E21.09

(57) ABSTRACT

A method for fabricating a semi-polar nitride semiconductor is disclosed, comprising following steps: firstly, a (001) substrate tilted at 7 degrees and having a plurality of V-like grooves is provided, and tilted surfaces of the V-like groove are a (111) surface at 61.7 degrees and a ( 1̅ 1̅1) surface at 47.7 degrees; next, a surface of said substrate is cleaned by using a deoxidized solution, and then a buffer layer is formed on said substrate to cover said V-like grooves; then, said buffer layer is covered with an oxide layer except for said buffer layer formed on said (111) surface at 61.7 degrees; and finally, said semi-polar nitride semiconductor is formed on said buffer layer having (111) surface at 61.7 degrees to enhance the quality of said semi-polar nitride semiconductor.

### BACKGROUND OF THE INVENTION

1. Field of the Invention

The present invention relates to a method for fabricating semi-polar nitride semiconductor, particularly to a method for fabricating semi-polar nitride semiconductor by using the characteristics of a buffer layer to enhance the quality of the semi-polar nitride semiconductor.

2. Description of the Related Art

The traditional semi-polar nitride semiconductor is like gallium nitride (GaN), which forms on the silicon substrate having periodical V-like grooves. Refer to FIG. 1 for a diagram schematically showing the semi-polar nitride semiconductor formed on a substrate according to the prior art. As shown in FIG. 1, the first step of forming the semi-polar nitride semiconductor is to form a silicon dioxide ridge-like periodical mask pattern, which is parallel to a [symbol] 1̅10 [symbol] direction on a (001) silicon substrate 10 tilted at 7 degrees. Next, the substrate 10 is etched to have V-like grooves 12 by using a potassium hydroxide (KOH) solution, wherein tilted surfaces of the V-like groove 12 are a (111) surface a and a ( 1̅ 1̅1) surface b, which respectively have inclined angles of 61.7 degrees and 47.7 degrees relative to a main surface of the substrate 10. Then, the V-like grooves 12 is covered with a silicon dioxide layer 14 except for the (111) surface a at 61.7 degrees, which is used as a growth region. Finally, a nucleation layer 16 containing silicon-doped aluminum indium nitride(Al_{0.85}In_{0.15}N) and having an approximate thickness of 10 nm is formed on the (111) surface a at 61.7 degrees with a metalorganic chemical vapor deposition method, so as to form a semi-polar nitride semiconductor as shown in FIG. 1.

But the above-mentioned method has three disadvantages as follows: (1). Since an oxide layer formed by itself on a silicon substrate can not be etched away by using a deoxidized layer solution, the GaN series materials can not be formed easily and their lattice qualities are inferior. (2). Since the difference of lattice constants is 17.9% for a silicon substrate and GaN, a nucleation layer must firstly be formed on the silicon substrate at a low temperature and in a high V/III ratio condition. Besides, the silicon substrate can be etched easily by Ga atoms, so the nucleation layer is usually made of strong-bonding & easily-nucleating aluminum nitride (AlN) series materials. Therefore, the nucleation layer can be formed easily to become a poly crystal type on silicon dioxide, thus the quality of the GaN material is decreased during growth process. (3). Moreover, although the GaN material can be grown to obtain a better quality at a high temperature (about 1100° C.), yet since the nucleation layer having a smaller thickness (the nucleation layer nucleates on silicon dioxide easily if the nucleation layer has a larger thickness) will cause silicon atoms to diffuse into the GaN material and result in a back-melting etching phenomena with GaN atoms when growing the GaN material at a high temperature, thus the surface of the GaN material becomes rough and the quality of the GaN material is decreased.

In view of the problems and shortcomings of the prior art, the present invention provides a brand new method for fabricating a semi-polar nitride semiconductor, so as to solve the afore-mentioned problems of the prior art.

### SUMMARY OF THE INVENTION

A primary objective of the present invention is to provide a method for fabricating a semi-polar nitride semiconductor, whereby a buffer layer is used to improve the quality of a semi-polar nitride semiconductor formed on a (001) substrate tilted at 7 degrees, lest the aluminum nitride (AlN) series materials used as a nucleate materials of prior art would form a poly crystal type on silicon dioxide, thus resulting in the nitride semiconductor grown subsequently to have a poor quality.

Another objective of the present invention is to provide a method for fabricating a semi-polar nitride semiconductor, which uses a deoxidized solution to remove an oxide layer grown by itself on a substrate, and then a buffer layer of a nitride semiconductor is formed on the substrate. Thus, the nitride semiconductor can be grown easily and the quality thereof is better.

A further objective of the present invention is to provide a method for fabricating a semi-polar nitride semiconductor, whereby when the semi-polar nitride semiconductor layer made of gallium nitride (GaN) is grown at a high temperature (about 1100° C.) in the fabricating process of the present invention, so as to have a better material quality. Therefore, silicon atoms will not diffuse into the GaN material, thus solving the problems of the back-melting etching phenomena generated by gallium (Ga) atoms, and the rough surfaces of the GaN material having the inferior material quality.

To achieve the above-mentioned objectives, the present invention provides a method for fabricating a semi-polar nitride semiconductor, comprising the following steps: firstly, a (001) substrate tilted at 7 degrees and having a plurality of V-like grooves is provided, and the tilted surfaces of the V-like groove are a (111) surface at 61.7 degrees and a ( 1̅ 1̅1) surface at 47.7 degrees. Next, the surface of the substrate is cleaned by using a deoxidized solution, and then a buffer layer is formed on the substrate to cover the V-like grooves. Then, the buffer layer is covered with an oxide layer except for the buffer layer formed on the (111) surface at 61.7 degrees. Finally, a semi-polar nitride semiconductor is formed on the buffer layer having (111) surface at 61.7 degrees to enhance the quality of the semi-polar nitride semiconductor.

Below, the embodiments are described in detail in cooperation with the drawings to facilitate understanding the characteristics, technical contents and accomplishments of the present invention.

### BRIEF DESCRIPTION OF THE DRAWINGS

FIG. 1 is a diagram schematically showing the semi-polar nitride semiconductor formed on a substrate according to the prior art; and

FIGS. 2A-2E are diagrams schematically showing the steps of forming a semi-polar nitride semiconductor formed a substrate according to the present invention.

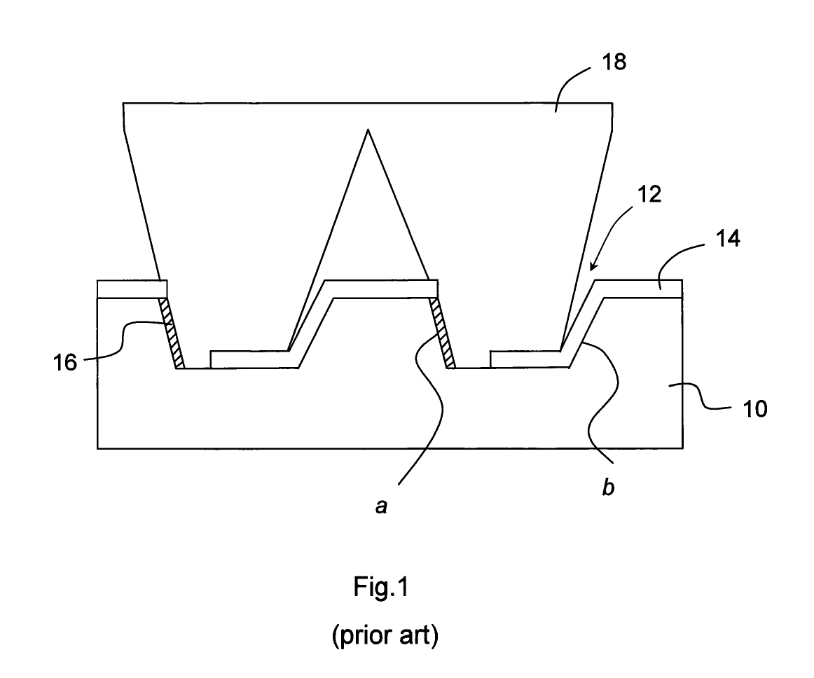

### DETAILED DESCRIPTION OF THE INVENTION

The fabricating process of the present invention is described by using the silicon substrate as an example, but the scope of the present invention is not so limited. In other words, the present invention is not only suited to the silicon substrate, but also suitable to substrate made of other materials.

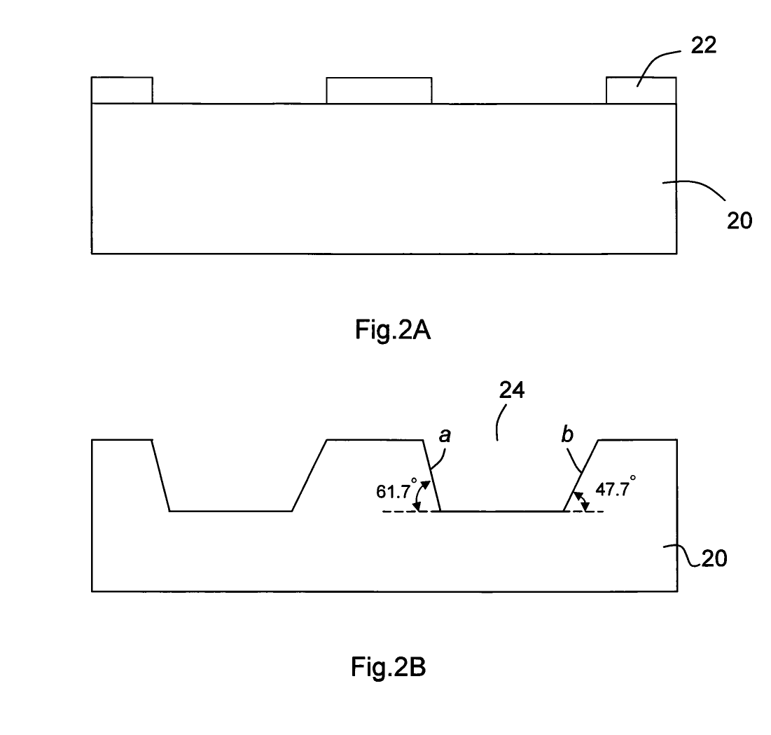

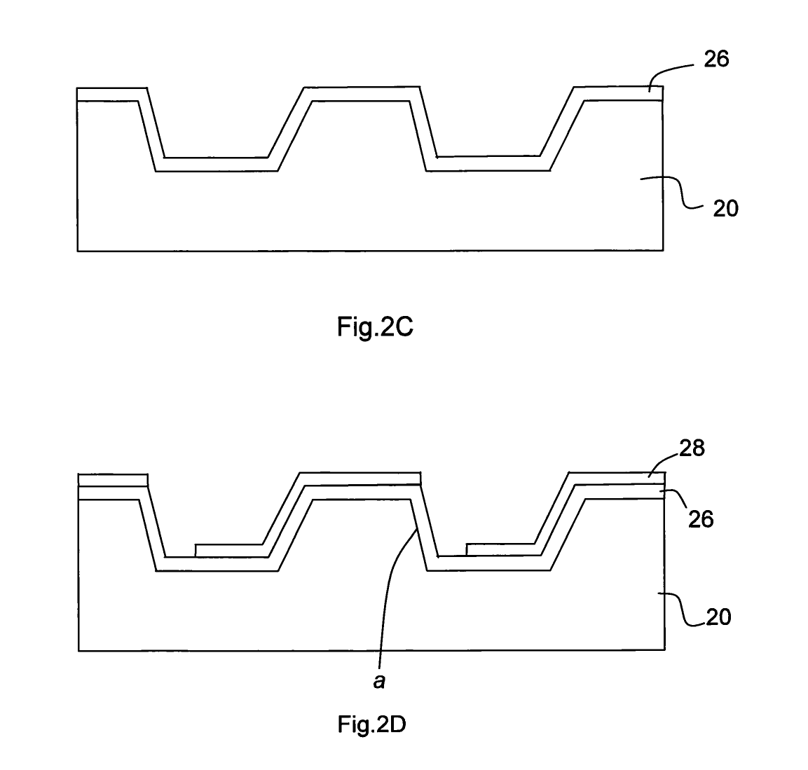

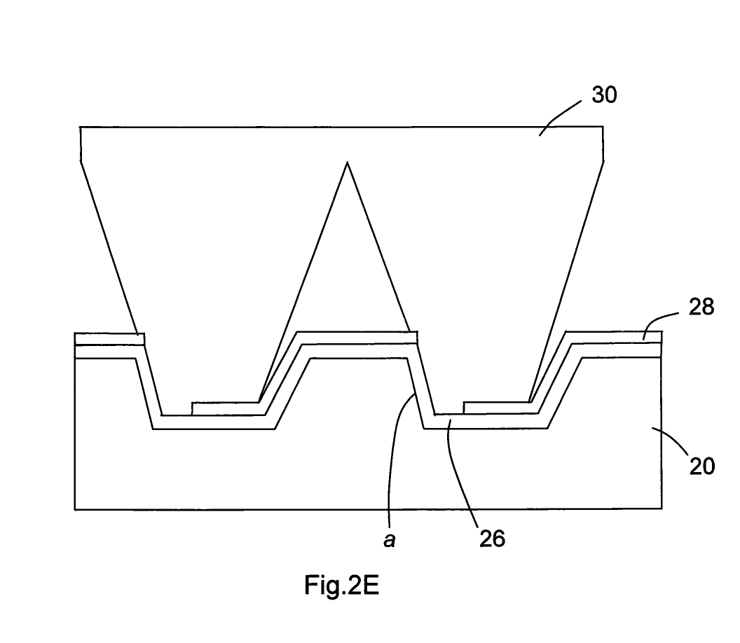

Refer to FIGS. 2A-2E for diagrams schematically showing the steps of a method for fabricating the semi-polar nitride semiconductor according to the embodiment of the present invention. As shown in FIG. 2A, a silicon dioxide ridge-like periodical mask pattern 22, which is parallel to a [symbol] 1̅10 [symbol] direction is formed on a (100) silicon substrate 20 tilted at 7 degrees by using the exposure and development processes. Next, as shown in FIG. 2B, the silicon substrate 20 exposed through the mask pattern 22 is etched to form V-like grooves 24 by using a etching solution, wherein tilted surfaces of the V-like groove 24 are a (111) surface a at 61.7 degrees and a ( 1̅ 1̅1) surface b at 47.7 degrees, and the etching solution is selected from a group consisting of: NH₄OH (ammonium hydroxide), KOH (potassium hydroxide+water), TMAH (tetramethylammoniumhydroxide+water), EDP (ethylenediamine+pyrocatechol+water), hydrazine (N₂H₄), sodium hydroxide (NaOH), lithium hydroxide (LiOH), or cesium hydroxide (CsOH) and so on. Then, the mask pattern 22 is removed.

Next, as shown in FIG. 2C, a surface of the silicon substrate 20 is cleaned by a deoxidized layer solution, such as hydrogen-fluoride (HF) or boron hydroxide (BOH). Next, a buffer layer 26 having a thickness of 20˜100 nm is formed on the silicon substrate 20, wherein the buffer layer 26 is made of a material selected from a group consisting of: a binary compound, a triple compound, a quad compound, or other materials having close lattice constants such as zinc oxide (ZnO). The binary compound comprises gallium nitride (GaN), aluminum nitride (AlN), and indium nitride (InN), the triple compound comprises aluminum gallium nitride (AlₓGa₁₋ₓN, 0≦x≦1), indium gallium nitride (InₓGa₁₋ₓN, 0≦x≦1), and the quad compound comprises aluminum gallium indium nitride (AlₓGa_{y}In_{1-x-y}N, 0≦x≦1, 0≦y≦1). Besides, the buffer layer 26 comprises a single layer material, a double layer material, or multi-layer material. The thickness of the buffer layer 26 is from 0.5 nm to a thickness that can fill up the V-like grooves. As shown in FIG. 2D, the buffer layer 26 is covered with an oxide layer 28 except for the buffer layer 26 formed on the (111) surface a at 61.7 degrees, wherein the oxide layer 28 comprises silicon dioxide or silicon nitride. Moreover, the oxide layer 28 is fabricated with a plasma-enhanced chemical vapor deposition system, an electro-beam evaporation system, a thermal-resistive evaporation system, or an ion sputtering system. Finally, as shown in FIG. 2E, a low-defective semi-polar nitride semiconductor layer 30 is formed on the buffer layer 26, that is formed on the (111) surface a at 61.7 degrees, wherein the semi-polar nitride semiconductor layer 30 is made of a material selected from a group consisting of: GaN, AlₓGa₁₋ₓN (0≦x≦1), InₓGa₁₋ₓN (0≦x≦1), AlₓGa_{y}In_{1-x-y}N (0<x<1, 0≦y≦1), or other materials having close lattice constants such as ZnO. Besides, the semi-polar nitride semiconductor layer 30 is fabricated using a molecular-beam epitaxy method, a metalorganic chemical vapor epitaxy method, or a hydride vapor epitaxy method. In other words, the semi-polar nitride semiconductor layer 30 can be fabricated by using any of the abovementioned methods or the above-mentioned methods in combination.

The buffer layer is fabricated using a molecular-beam epitaxy method, a metalorganic chemical vapor epitaxy method, or a hydride vapor epitaxy method. In other words, the buffer layer can be fabricated using any of the above-mentioned methods or the above-mentioned methods in combination.

The present invention uses the characteristics of the buffer layer to improve the semi-polar (1 1̅01) nitride semiconductor formed on the (001) substrate tilted at 7 degrees by the steps of the above-mentioned fabricating process. Besides, the oxide layer grown by itself on the substrate is removed by using the deoxidized solution, such as HF or BOE, and then the buffer layer is formed on the substrate to enhance the growth and quality of the nitride semiconductor material.

Furthermore, the fabricating steps of the present invention can be used to avoid the problem of the prior art that AlN series materials used as a nucleate material becoming a poly crystal type material on silicon dioxide, and that causes the nitride semiconductor grown subsequently to have inferior quality.

When the semi-polar nitride semiconductor layer is made of GaN, the GaN material is grown at a high temperature (about 1100° C.) during the fabricating process of the present invention, so as to have a better material quality. Therefore, silicon atoms will not diffuse into the GaN material. The back-melting etching phenomena generated by Ga atoms and the rough surface of the GaN material having inferior material quality will not occur as well.

The embodiments described above are only to exemplify the present invention but not to limit the scope of the present invention. Therefore, any equivalent modification or variation according to the shape, structures, characteristics and spirit disclosed in the present invention is to be also included within the scope of the present invention.

What is claimed is:

1. A method for fabricating a semi-polar nitride semiconductor, comprising steps of:
providing a (001) substrate tilted at 7 degrees and having a plurality of V-like grooves, wherein tilted surfaces of each said V-like groove are a (111) surface at 61.7 degrees and a ( 1̅ 1̅1) surface at 47.7 degrees;
using a deoxidized layer solution to clean a surface of said substrate;
forming a buffer layer on said substrate to cover said V-like grooves;
forming an oxide layer over said buffer layer except for said buffer layer formed on said (111) surface at 61.7 degrees; and
forming a semi-polar nitride semiconductor on said buffer layer, and that is formed on said (111) surface at 61.7 degrees.

2. The method for fabricating a semi-polar nitride semiconductor according claim 1, wherein said substrate is a silicon substrate.

3. The method for fabricating a semi-polar nitride semiconductor according claim 1, wherein said buffer layer comprises a binary compound, a triple compound, a quad compound, or other materials having close lattice constants such as zinc oxide (ZnO), wherein said binary compound comprises gallium nitride (GaN), aluminum nitride (AlN), and indium nitride (InN), said triple compound comprises aluminum gallium nitride (AlₓGa₁₋ₓN, 0≦x≦1), indium gallium nitride (InₓGa₁₋ₓN, 0≦x≦1), and said quad compound comprises aluminum gallium indium nitride (AlₓGa_{y}In_{1-x-y}N, 0≦x≦1, 0≦y≦1).

4. The method for fabricating a semi-polar nitride semiconductor according claim 1, wherein a thickness of said buffer layer is from 0.5 nm to a thickness that can fill up said V-like grooves.

5. The method for fabricating a semi-polar nitride semiconductor according claim 1, wherein said buffer layer comprises a single layer material, a double layer material, or a multi-layer material.

6. The method for fabricating a semi-polar nitride semiconductor according claim 1, wherein said buffer layer is fabricated using a molecular-beam epitaxy method, a metalorganic chemical vapor epitaxy method, a hydride vapor epitaxy method, or said above-mentioned methods in combination.

7. The method for fabricating a semi-polar nitride semiconductor according claim 1, wherein said oxide layer comprises silicon dioxide or silicon nitride.

8. The method for fabricating a semi-polar nitride semiconductor according claim 1, wherein said oxide layer is fabricated with a plasma-enhanced chemical vapor deposition system, an electro-beam evaporation system, a thermal-resisted evaporation system, or an ion sputtering system.

9. The method for fabricating a semi-polar nitride semiconductor according claim 1, wherein a material of said nitride semiconductor is selected from following materials: GaN, AlₓGa₁₋ₓN (0≦x≦1), InₓGa₁₋ₓN (0≦x≦1), AlₓGa_{y}In_{1-x-y}N (0<x<1, 0≦y≦1); or other materials having close lattice constants such as ZnO.

10. The method for fabricating a semi-polar nitride semiconductor according claim 1, wherein said semi-polar nitride semiconductor is fabricated using one of following methods: a molecular-beam epitaxy method, a metalorganic chemical vapor epitaxy method, a hydride vapor epitaxy method; or said above-mentioned methods in combination.

11. The method for fabricating a semi-polar nitride semiconductor according claim 9, wherein when said material of said nitride semiconductor is GaN, said nitride semiconductor is grown at a temperature of 1100° C.
